(19) United States
(12) Patent Application Publication
(10) Pub. No.: US 2026/0136821 A1
(43) Pub. Date: May 14, 2026

(54) DISPLAY PANEL AND DISPLAY APPARATUS

(71) Applicants: Chengdu BOE Optoelectronics Technology Co., Ltd., Sichuan (CN); BOE Technology Group Co., Ltd., Beijing (CN)

(72) Inventors: Ren Xiong, Beijing (CN); Wei Qing, Beijing (CN); Fengping Wu, Beijing (CN); Zhihui Wang, Beijing (CN)

(73) Assignees: Chengdu BOE Optoelectronics Technology Co., Ltd., Sichuan (CN); BOE Technology Group Co., Ltd., Beijing (CN)

(21) Appl. No.: 18/696,061

(22) PCT Filed: Jul. 31, 2023
(86) PCT No.: PCT/CN2023/110349

§ 371 Date: Mar. 27, 2024

(30) Foreign Application Priority Data
Aug. 25, 2022 (CN) 202211025691.1

(51) Int. Cl. H10K 77/10; H10K 59/80; H10K 59/82; H10K 102/00

(52) U.S. Cl. CPC H10K 77/111; H10K 59/82; H10K 59/8794; H10K 2102/311; H10K 2102/351

(57) ABSTRACT

The present disclosure provides a display panel and a display apparatus, which relates to the technical field of displaying. A substrate in the display panel ensures support for the display panel, and at the same time, the display panel can realize a narrow border. The display panel includes a device provision area, a bending area and a binding area. The bending area is located between the device provision area and the binding area. The display panel further includes a substrate and a display baseplate arranged on the substrate, and the display baseplate is located in the device provision area. The substrate is located in the device provision area, the bending area and the binding area, and at least includes a rigid substrate, and a part of the substrate located in the bending area is configured to be bendable along a bending axis.

### CROSS-REFERENCES TO RELATED APPLICATIONS

This application claims priority to the Chinese patent application No. 202211025691.1 entitled “DISPLAY PANEL AND DISPLAY APPARATUS” filed in China National Intellectual Property Administration on Aug. 25, 2022, which is incorporated herein by reference in their entirety.

### TECHNICAL FIELD

The present disclosure relates to the technical field of displaying, in particular to a display panel and a display apparatus.

### BACKGROUND

With development of science and technology, OLED (Organic Light Emitting Diode) display products have been more and more widely used. At present, a PI (Polyimide) film is often used as a base material in the OLED display products, which can make the OLED display products to achieve bending, but the PI base material provides no support.

Therefore, it is urgent to provide a new display product that allows the base material to provide support and also has a narrow border.

### SUMMARY

Embodiments of the present disclosure provide following technical solutions.

In an aspect, a display panel and a display apparatus are provided. The display panel includes a device provision area, a bending area and a binding area. The bending area is located between the device provision area and the binding area; and

the display panel further includes a substrate and a display baseplate arranged on the substrate, and the display baseplate is located in the device provision area; the substrate is located in the device provision area, the bending area and the binding area, and at least includes a rigid substrate, and a part of the substrate located in the bending area is configured to be bendable along a bending axis.

Optionally, the substrate comprises the rigid substrate and a flexible substrate disposed between the rigid substrate and the display baseplate; wherein the rigid substrate is located in the device provision area; the flexible substrate is located in the device provision area, the bending area and the binding area, and a part of the flexible substrate located in the bending area is configured to be bendable along the bending axis; and

the display panel further comprises a plurality of driving units provided on a side of the flexible substrate close to the display baseplate, and the plurality of driving units are uniformly distributed in the binding area.

Optionally, a length of the part of the flexible substrate located in the bending area in a direction parallel to the display baseplate is different from at least one of a length of a part of the flexible substrate located in the device provision area in the direction parallel to the display baseplate and a length of a part of the flexible substrate located in the binding area in the direction parallel to the display baseplate.

Optionally, the length of the part of the flexible substrate located in the bending area in the direction parallel to the display baseplate is respectively less than the length of the part of the flexible substrate located in the device provision area in the direction parallel to the display baseplate and the length of the part of the flexible substrate located in the binding area in the direction parallel to the display baseplate.

Optionally, at least one cut corner is respectively provided at a side, close to the bending area, of the part of the flexible substrate located in the device provision area and a side, close to the bending area, of the part of the flexible substrate located in the binding area.

Optionally, the part of the flexible substrate located in the bending area and the part of the flexible substrate located in the binding area both comprise a plurality of flexible substrate sections that are disconnected, and a through groove is provided between adjacent flexible substrate sections; and

respective driving units are arranged on respective flexible substrate sections.

Optionally, an orthographic projection of an outer contour of the through groove on the substrate comprises a first line segment, a second line segment and a third line segment, the first line segment is arranged close to the device provision area, and one end of the first line segment is connected to the second line segment and the other end of the first line segment is connected to the third line segment.

Optionally, the orthographic projection of the outer contour of the through groove on the substrate further comprises a fourth line segment and a fifth line segment; and one end of the first line segment is connected to the second line segment through the fourth line segment, and the other end of the first line segment is connected to the third line segment through the fifth line segment.

Optionally, the display panel further comprises a heat dissipation layer and a spacer stacked on a side of the rigid substrate away from the display baseplate, and both the heat dissipation layer and the spacer are located in the device provision area; and the display panel further comprises a support layer provided on a side of the flexible substrate away from the display baseplate, the support layer is located in the binding area, and orthographic projections of the driving units on the flexible substrate are located within an orthographic projection of the support layer on the flexible substrate; the support layer is configured to contact the spacer after the part of the flexible substrate located in the bending region is bent along the bending axis.

Optionally, the substrate comprises the rigid substrate, the rigid substrate is located in the device provision area, the bending area and the binding area; and a part of the rigid substrate located in the bending region is configured to be bendable along the bending axis.

Optionally, a thickness of the rigid substrate in the direction perpendicular to the display baseplate is uniform.

Optionally, the thickness of the rigid substrate in the direction perpendicular to the display baseplate ranges from 0.03 mm to 0.07 mm.

Optionally, a thickness of the part of the rigid substrate located in the bending area in the direction perpendicular to the display baseplate is respectively less than a thickness of a part of the rigid substrate located in the device provision area in the direction perpendicular to the display baseplate and a thickness of a part of the rigid substrate in the binding area in the direction perpendicular to the display baseplate.

Optionally, the display panel further comprises a heat dissipation layer and a spacer stacked on a side of the rigid substrate away from the display baseplate, both the heat dissipation layer and the spacer are located in the device provision area; and the part of the rigid substrate located in the binding area is configured to contact the spacer after the part of the rigid substrate located in the bending area is bent along the bending axis.

In another aspect, a display apparatus is provided, which includes the display panel described above.

The above description is only an overview of the technical solution of the present disclosure. In order to have a clearer understanding of the technical means of the present disclosure, it can be implemented according to the content of the specification. In order to make the above and other purposes, features, and advantages of the present disclosure more obvious and easier to understand, the specific implementation methods of the present disclosure are listed below.

### BRIEF DESCRIPTION OF THE DRAWINGS

In order to provide a clearer explanation of technical solutions in the embodiments of the present disclosure or in prior art, a brief introduction will be made to the accompanying drawings required in description of the embodiments or prior art. It is evident that the accompanying drawings in the following description are only some embodiments of the present disclosure. For those skilled in the art, other accompanying drawings can be obtained based on these drawings without creative labor.

FIG. 1 is a schematic structural diagram of a display panel in related art;

FIG. 2 is a schematic structural diagram of a display panel according to an embodiment of the present disclosure;

FIG. 3 is a schematic structural diagram of another display panel according to an embodiment of the present disclosure;

FIG. 4 is a top view of a display panel according to an embodiment of the present disclosure;

FIG. 5 is a simulation diagram of the display panel in FIG. 4;

FIG. 6 is a top view of another display panel according to an embodiment of the present disclosure;

FIG. 7 is a top view of yet another display panel according to an embodiment of the present disclosure;

FIG. 8 is a simulation diagram of the display panel in FIG. 7;

FIG. 9 is a schematic structural diagram of a groove according to an embodiment of the present disclosure;

FIG. 10 is a schematic structural diagram of another groove according to an embodiment of the present disclosure;

FIG. 11 is a schematic structural diagram of yet another groove according to an embodiment of the present disclosure;

FIG. 12 is a schematic structural diagram of yet another display panel according to an embodiment of the present disclosure; and

FIG. 13 is a schematic structural diagram of still another display panel according to an embodiment of the present disclosure.

### DETAILED DESCRIPTION

The following will provide a clear and complete description of the technical solution in the embodiments of the present disclosure, in conjunction with the accompanying drawings. Obviously, the described embodiments are only a part of the embodiments of the present disclosure, not all of them. Based on the embodiments in the present disclosure, all other embodiments obtained by persons skilled in the art without creative labor fall within the scope of protection of the present disclosure.

In the embodiments of the present disclosure, the use of words such as “first”, “second”, “third”, “fourth”, and “fifth” to distinguish similar or identical items with similar functions and effects is only for the purpose of clearly describing the technical solution of the embodiments of the present disclosure, and cannot be understood as indicating or implying relative importance or implying the number of indicated technical features.

In the embodiments of the present disclosure, “plurality of” means two or more, and “at least one” means one or more, unless otherwise specified.

In the embodiments of the present disclosure, the terms “up” and the like indicate orientation or positional relationships based on the orientation or positional relationships shown in the drawings, only for the convenience of describing the present disclosure and simplifying the description, rather than indicating or implying that the device or component referred to must have a specific orientation, be constructed and operated in a specific orientation, and therefore cannot be understood as a limitation of the present disclosure.

With development of science and technology, display products have been more and more widely used, among which LCD (Liquid Crystal Display) and OLED display panels are very widely used. At present, in the LCD display panel, a glass substrate provides support for base materials, and in the OLED display panel, a PI film is often used as a base material, but the PI base material provides no support, and thus a CG (Glass Cover) is often added on a surface of the OLED display panel to enhance its support. However, due to the CG cover provided in the OLED display panel, there are problems of the OLED display panel such as a large thickness and high production cost.

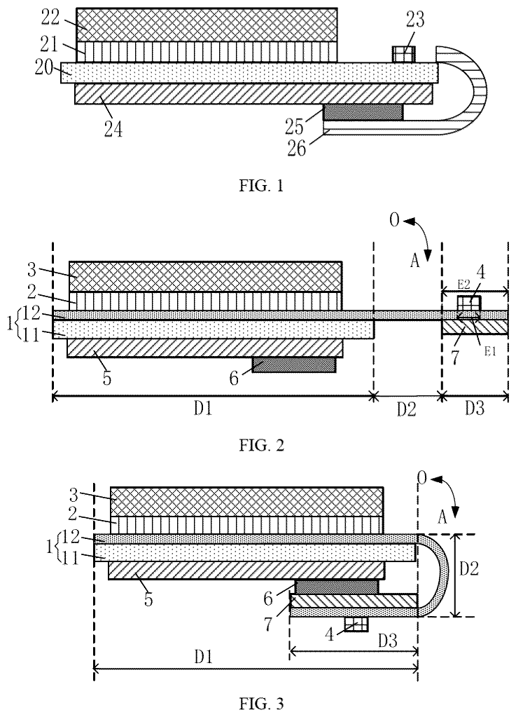

In order to solve above problems, existing OLED products on the market such as NB (Note Book) products usually adopt a design solution of a rigid substrate and a flexible package so as to provide support for the OLED products. However, because the rigid substrate itself is of a rigid material that cannot be bent, a side of the OLED product such as a lower frame cannot be bent, and only a FPC (Flexible Printed Circuit board) bending solution or a COF (Chip On Film) bending solution as shown in FIG. 1 can be carried out, resulting in that a narrow border cannot be implemented in OLED products. Referring to FIG. 1, an OLED display panel 21 and a TFE (Thin Film Encapsulation) layer 22 are sequentially stacked on a glass substrate 20, and a driving chip 23 is arranged on a glass substrate 11. Meanwhile, an SCF layer (heat dissipation layer) 24, a spacer layer 25 and an FPC (Flexible Printed Circuit board) 26 are sequentially stacked on a side of the glass substrate 20 away from the OLED display panel 21. In this case, the OLED display panel 21 can only be bent by bending the FPC 26.

Based on the above, an embodiment of the present disclosure provides a display panel, which, as shown in FIGS. 2 to 3 and 12 to 13, includes a device provision area D1, a bending area D2 and a binding area D3. The bending area D2 is located between the device provision area D1 and the binding area D3.

Referring to FIGS. 2 to 3 and 12 to 13, the display panel further includes a substrate 1 and a display baseplate 2 provided on the substrate 1, and the display baseplate 2 is located in the device provision area D1. The substrate 1 is located in the device provision area D1, the bending area D2 and the binding area D3, and includes at least a rigid substrate 11. A part of the substrate 1 located in the bending area D2 is configured to be bendable along a bending axis.

The device provision area described above refers to an area for providing display apparatuses, and the binding area described above refers to an area for binding driving chips, circuit boards and the like. A display apparatus is formed by providing a display apparatus, a driving chip, a circuit board and the like on a display panel.

The bending area described above refers to an area that can be bent in a specific direction (for example, an OA direction shown in FIG. 2).

The substrate described above including at least the rigid substrate means that the substrate described above only includes the rigid substrate; or, the substrate described above includes a substrate made of other materials, such as a flexible substrate, in addition to the rigid substrate.

A material and a thickness of the rigid substrate are not specifically limited herein. For example, the material of the rigid substrate can be glass or the like. For example, a thickness of the rigid substrate in a direction perpendicular to the display baseplate may range from 0.3 mm to 0.6 mm. Specifically, the thickness of the rigid substrate in the direction perpendicular to the display baseplate may be 0.3 mm, 0.4 mm, 0.5 mm, or 0.6 mm, etc.

The display baseplate may be a flexible display baseplate such as an OLED display baseplate; or a rigid display baseplate such as an LCD display baseplate, which is not limited herein. The embodiments provided in the present disclosure are all schematically illustrated by taking an OLED display baseplate as the above display baseplate as an example.

It should be noted that the bending axis described above is not an actual structure existing in the display panel, but a concept proposed to illustrate a bending process of the display panel.

A bending direction of the display panel is also not limited herein. For example, the bending direction may be the OA direction as shown in FIGS. 2 and 3, or it may be an AO direction. The bending direction can be specifically determined according to actual situation. The embodiments provided in the present disclosure are all illustrated by taking bending of the display panel described above along the OA direction as an example.

In addition, as shown in FIG. 2 to FIG. 3 and FIG. 12 to FIG. 13, the display panel further includes an encapsulation layer 3 provided on a side of the display baseplate 2 away from the rigid substrate 11. A structure of the encapsulation layer is not specifically limited herein. For example, the encapsulation layer may include only one layer, such as an inorganic layer; or the encapsulation layer can be of a TFE encapsulation type, specifically including a first inorganic encapsulation layer, an organic encapsulation layer and a second inorganic encapsulation layer, which depends on actual applications.

The display panel according to the embodiment of the present disclosure includes the device provision area, the bending area and the binding area. The bending area is located between the device provision area and the binding area. The display panel further includes the substrate and the display baseplate arranged on the substrate, and the display baseplate is located in the device provision area. The substrate is located in the device provision area, the bending area and the binding area, and at least includes the rigid substrate, and the part of the substrate located in the bending area is configured to be bendable along the bending axis. In this way, while support for the display panel is ensured by the rigid substrate, bending of the display panel can also be realized with the bending area of the substrate. Thus, not only rigidity of the display panel can be kept, but also a one-sided border of the display panel such as a lower border can be bent easily, so that the narrow border can be realized for the display panel.

Optionally, as shown in FIG. 2 and FIG. 3, the substrate 1 includes a rigid substrate 11 and a flexible substrate 12 arranged between the rigid substrate 11 and the display baseplate 2. The rigid substrate 11 is located in the device provision area D1, and the flexible substrate 12 is located in the device provision area D1, the bending area D2 and the binding area D3, and a part of the flexible substrate 12 located in the bending area D2 is configured to be bendable along the bending axis.

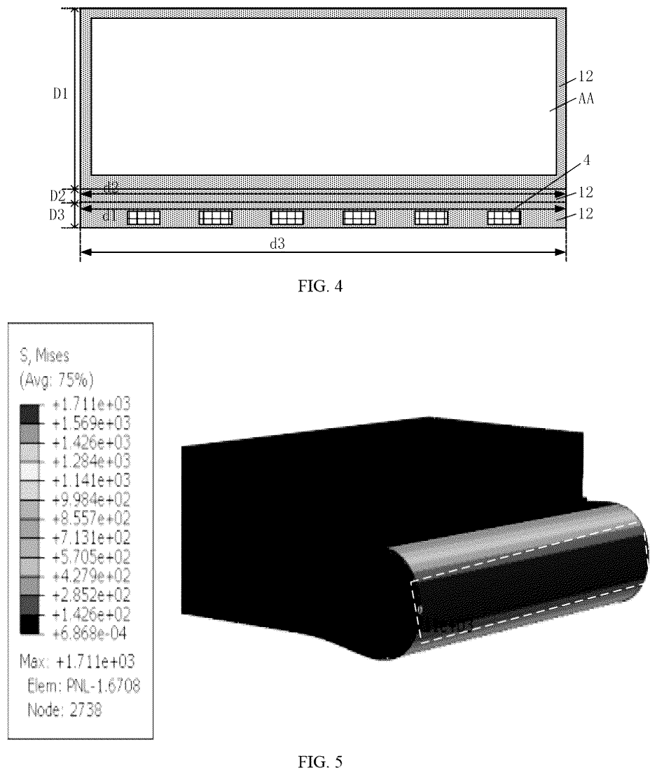

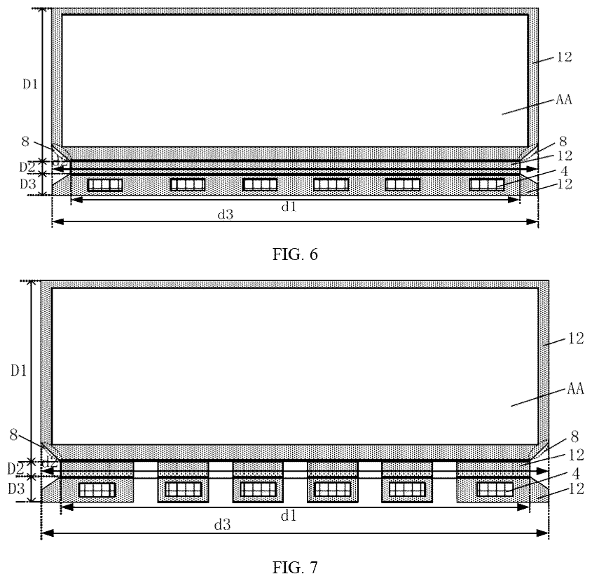

Referring to FIGS. 4 and 6, the display panel further includes a plurality of driving units 4 provided on a side of the flexible substrate 12 close to the display baseplate (a display area AA of the display baseplate shown in the figure), and the plurality of driving units 4 are uniformly distributed in the binding area D3. Therefore, by using the rigid substrate and the flexible substrate as a substrate in both the display area and a non-display area of the display panel, support for the display panel is well realized. Meanwhile, because the flexible substrate is adopted in the bending area, bending of the display panel can be realized, thus realizing the narrow border.

A material and a thickness of the flexible substrate are not specifically limited herein. For example, the material of the flexible substrate can be PI or the like. For example, a thickness of the flexible substrate in the direction perpendicular to the display baseplate may range from 20 μm to 50 μm. Specifically, the thickness of the flexible substrate in the direction perpendicular to the display baseplate may be 20 μm, 30 μm, 40 μm or 50 μm, etc.

Here, a structure of the driving unit is not specifically limited. For example, the driving unit may be a driving chip or the like.

Here, among the plurality of driving units, a spacing between adjacent driving units is not limited, but is specifically determined by an area of the binding area and a number of driving units.

It should be noted that the rigid substrate and the flexible substrate may be formed in sequence firstly, and then the display baseplate may be formed on the flexible substrate, in which case both the rigid substrate and the flexible substrate may be arranged in the device provision area, the bending area and the binding area. Then, the rigid substrate in the bending area and the binding area are removed in an EAC section (cutting, thinning and other sections of the display panel).

Optionally, as shown in FIGS. 4 and 6 to 7, a length dl of a part of the flexible substrate 12 located in the bending area D2 in a direction parallel to the display baseplate is different from at least one of a length d2 of a part of the flexible substrate 12 located in the device provision area D1 in the direction parallel to the display baseplate and a length d3 of a part of the flexible substrate 12 located in the binding area D3 in the direction parallel to the display baseplate.

Certainly, as shown in FIGS. 6 to 7, it is possible that the length d1 of the part of the flexible substrate 12 located in the bending area D2 in the direction parallel to the display baseplate is the same as at least one of the length d2 of the part of the flexible substrate 12 located in the device provision area D1 in the direction parallel to the display baseplate and the length d3 of the part of the flexible substrate 12 located in the binding area D3 in the direction parallel to the display baseplate. In a case that the length d1 is the same as at least one of the length d2 and the length d3, it can be that the length d1 is the same as the length d2; or the length d1 is the same as the length d3; or the length d1 is the same as both the length d2 and the length d3. A case that the length d1 is the same as both the length d2 and the length d3 is taken as an example in FIG. 4. In this case, the flexible substrate can be conveniently manufactured, which is simple and easy to implement. However, it is found after simulation of the display panel with this structure that, as shown in FIG. 5, a stress value of the bending area in a dotted frame is approximately 1.711e+03, which is relatively large, and a stress is concentrated in the bending area, which is easy to cause problems such as cracks in the bending area.

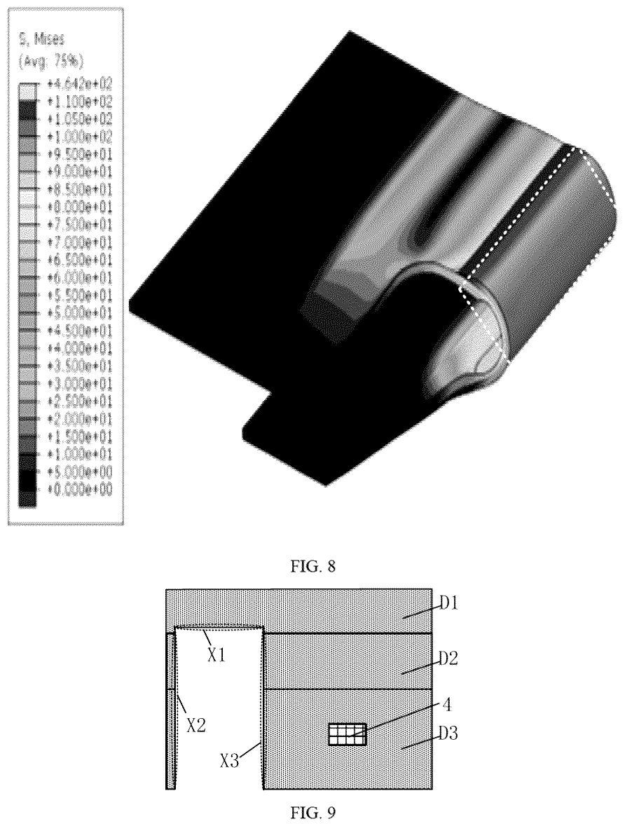

In a case that the length d1 is different from at least one of the length d2 and the length d3, it can be that the length d1 is different from the length d2; or the length d1 is different from the length d3; or the length d1 is different from both the length d2 and the length d3. A case that the length d1 is different from both the length d2 and the length d3, and the length d2 is the same as the length d3 is taken as an example in FIGS. 6 and 7. In this case, it is found after simulation of the display panel with the structure shown in FIG. 7, as shown in FIG. 8, a stress value of the bending area in the dotted frame is approximately 5.500e+01, which is significantly less, especially less than the stress value in the dotted frame in FIG. 5, and thus problems such as bending cracks can be effectively reduced.

It should be noted that relationship between the length d2 and the length d3 is not specifically limited in any of above cases, and the length d2 and the length d3 can be the same or different, which depends on actual applications.

Optionally, as shown in FIGS. 6 and 7, the length d1 of the part of the flexible substrate 12 located in the bending area D2 in the direction parallel to the display baseplate is respectively less than the length d2 of the part of the flexible substrate 12 located in the device provision area D1 in the direction parallel to the display baseplate and the length d3 of the part of the flexible substrate 12 located in the binding area D3 in the direction parallel to the display baseplate. In this case, the stress in the bending area can be reduced below a safe value, and problems such as the cracks in the bending area can be reduced or even avoided.

Here, relationship between the length d2 and the length d3 is not specifically limited. For example, the length d2 may be the same as the length d3; or the length d2 may be different from the length d3. A case that the length d2 may be the same as the length d3 is taken as an example in FIG. 6.

Optionally, referring to FIG. 6, at least one cut corner 8 is respectively provided at a side, close to the bending area D2, of the part of the flexible substrate 12 located in the device provision area D1 and a side, close to the bending area D2, of the part of the flexible substrate 12 located in the binding area D3. Therefore, when the flexible substrate in the bending area is manufactured, a length of the flexible substrate in the bending area in the direction parallel to the display panel is limited to an edge of the cut corner, and the length of the flexible substrate in the bending area in the direction parallel to the display panel can be realized to be minimized. That is, an edge of the display panel is cut obliquely, thus reducing a total length of the flexible substrate in the bending area.

Here, a number of the cut corners is not specifically limited. For example, there may be one cut corner; or there may be a plurality of cut corners. A case that there are two cut corners 8 at the side, close to the bending area D2, of the part of the flexible substrate 12 located in the device provision area D1 and there are two cut corners 8 at the side, close to the bending area D2, of the part of the flexible substrate 12 located in the binding area D3 is taken as an example in FIG. 6.

Optionally, as shown in FIG. 6, a shape of an outer contour of an orthographic projection of the part of the flexible substrate 12 located in the device provision area D1 on the substrate and an outer contour shape of an orthographic projection of the part of the flexible substrate 12 located in the binding area D3 on the substrate are both rectangles with two cut corners 8.

Optionally, as shown in FIGS. 4 and 6, the part of the flexible substrate 12 located in the bending area D2 and the part of the flexible substrate 12 located in the binding area D3 are both integral structures. In this case, the flexible substrate can be conveniently manufactured, which is simple and easy to implement.

Optionally, as shown in FIG. 7, both the part of the flexible substrate 12 located in the bending area D2 and the part of the flexible substrate 12 located in the binding area D3 include a plurality of flexible substrate sections that are disconnected, and there is a through groove between adjacent flexible substrate sections; respective driving units 4 are arranged on respective flexible substrate sections 12. In this way, problems of tearing and breaking of the flexible substrate in the bending area can be effectively reduced or even avoided.

Here, a forming process of the groove is not specifically limited. For example, a laser process can be used to remove the flexible substrate in the bending area, the binding area, and the like.

It should be noted that a small part of the flexible substrate at a side of the device provision area close to the bending area can also be removed by the laser process to further prevent the bending area from tearing and breaking.

Optionally, as shown in FIGS. 9 to 11, an orthographic projection of an outer contour of the groove on the substrate includes a first line segment X1, a second line segment X2 and a third line segment X3. The first line segment X1 is arranged close to the device provision area D1, and one end of the first line segment X1 is connected to the second line segment X2 and the other end of the first line segment is connected to the third line segment X3. In this way, the adjacent flexible substrate sections are disconnected, that is, lengths of parts of the flexible substrate in the bending area and the binding area along the direction parallel to the display panel is further reduced, and the problems of tearing, breaking and the like of the flexible substrate in the bending area are further reduced or even avoided.

Specific ways in which the second line segment is connected to one end of the first line segment and the third line segment is connected to the other end of the first line segment are not limited herein. For example, the second line segment can be directly or indirectly connected to one end of the first line segment, and the third line segment can also be directly or indirectly connected to the other end of the first line segment.

Shapes of the first line segment, the second line segment and the third line segment are not specifically limited herein. For example, the first line segment, the second line segment and the third line segment may all be straight lines as shown in FIGS. 9 to 11.

Optionally, as shown in FIG. 9, one end of the first line segment X1 is directly connected to the second line segment X2, and the other end of the first line segment is directly connected to the third line segment X3. In this way, respective line segments can be conveniently manufactured, which is simple and easy to implement.

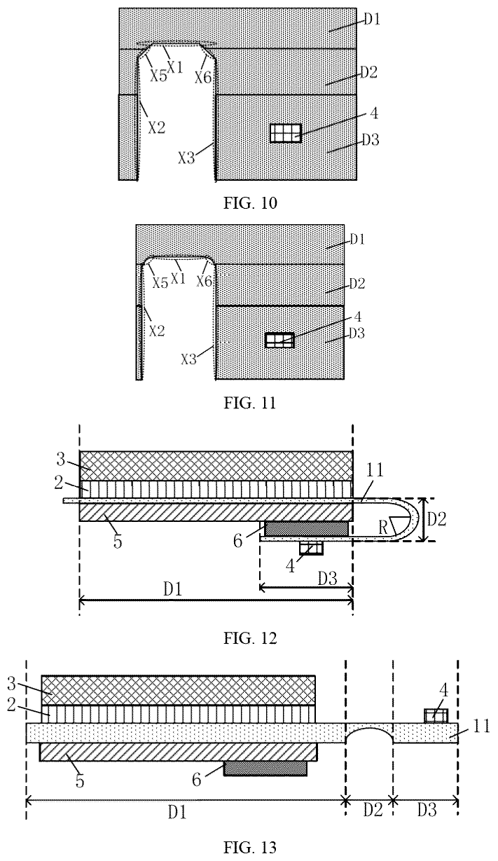

Optionally, as shown in FIGS. 10 to 11, the orthographic projection of the outer contour of the groove on the substrate further includes a fourth line segment X5 and a fifth line segment X6. One end of the first line segment X1 is connected to the second line segment X2 through the fourth line segment X5, and the other end of the first line segment is connected to the third line segment X3 through the fifth line segment X6. In this way, the first line segment and the second line segment can be prevented from being directly connected by a right angle, and the first line segment and the third line segment can be prevented from being directly connected by a right angle, so that the problems of tearing, breaking and the like of the flexible substrate in the bending area can be further reduced.

Shapes of the fourth line segment and the fifth line segment are not specifically limited herein. For example, the shapes of the fourth line segment and the fifth line segment may be the same, but of course they may be different.

Optionally, as shown in FIGS. 10 to 11, the shapes of the fourth line segment and the fifth line segment both can be straight lines or arcs.

Optionally, as shown in FIGS. 2 and 3, the display panel further includes a heat dissipation layer 5 and a spacer 6 stacked on a side of the rigid substrate 11 away from the display baseplate 2, and both the heat dissipation layer 5 and the spacer 6 are located in the device provision area D1.

As shown in FIGS. 2 and 3, the display panel further includes a support layer 7 provided on a side of the flexible substrate 12 away from the display baseplate 2, the support layer 7 is located in the binding area D2, and orthographic projections E1 of the driving units 4 on the flexible substrate 12 are located within an orthographic projection E2 of the support layer 7 on the flexible substrate 12. The support layer 7 is configured to contact the spacer 6 after the part of the flexible substrate 12 located in the bending region D2 is bent along the bending axis. In this way, the display panel can be well heat dissipated by the heat dissipation layer, and strength of the driving unit and the like during bonding can be ensured with the supporting layer, so as to ensure binding effect.

A material of the heat dissipation layer is not specifically limited herein. For example, the material of the heat dissipation layer can be copper foil, foam, etc.

A material of the spacer is not specifically limited herein. For example, a material of the spacer can be platinum (Pt).

A material of the support layer is not specifically limited herein. For example, the material of the support layer can be a material with a high modulus and high strength, such as PI, PP (Polypropylene) and the like.

Optionally, as shown in FIGS. 12 and 13, the substrate includes a rigid substrate 11, and the rigid substrate 11 is located in the device provision area D1, the bending area D2 and the binding area D3. A part of the rigid substrate 11 located in the bending region D2 is configured to be bendable along the bending axis. Therefore, UTG technology can be used to provide a bendable rigid substrate, and the narrow border of the display panel can be realized only by bending the rigid substrate, while strength of the bending area is also improved.

A material and a thickness of the rigid substrate are not specifically limited herein. For example, the material of the rigid substrate may include glass and special materials. For example, a thickness of the rigid substrate in the direction perpendicular to the display baseplate may range from 0.03 mm to 0.07 mm, so that this ultra-thin rigid substrate can be bent.

It should be noted that the display baseplate can be made directly on the rigid substrate, and this design requires no substrate stripping and treatment in the EAC section, which is simple and easy to implement.

In addition, due to bendable characteristics of the ultra-thin rigid substrate, bending with a less radius can be realized. For example, R in FIG. 12 can range from 0.5 mm to 1.5 mm, and specifically, a radius of the bending area can be 0.5 mm, 0.7 mm, 0.8 mm, 1.0 mm or 1.5 mm, etc., so that display products can be applied to fields such as vehicles.

Optionally, as shown in FIG. 12, the thickness of the rigid substrate 11 in the direction perpendicular to the display baseplate 2 is uniform. In this way, the rigid substrate can be conveniently manufactured, and the method is simple and easy to implement.

Optionally, a thickness of the rigid substrate in the direction perpendicular to the display baseplate ranges from 0.03 mm to 0.07 mm.

The thickness of the rigid substrate in the direction perpendicular to the display baseplate is not specifically limited herein. For example, the thickness of the rigid substrate in the direction perpendicular to the display baseplate may be 0.03 mm, 0.04 mm, 0.05 mm, 0.06 mm or 0.03 mm, etc.

Optionally, as shown in FIG. 13, a thickness of the part of the rigid substrate 11 located in the bending area D2 in the direction perpendicular to the display baseplate 2 is respectively less than a thickness of a part of the rigid substrate 11 located in the device provision area D1 in the direction perpendicular to the display baseplate 2 and a thickness of a part of the rigid substrate 11 in the binding area D3 in the direction perpendicular to the display baseplate 2. In this way, the part of the rigid substrate located in the bending area can be bent only by processing the part of the rigid substrate located in the bending area, so as to realize the narrow border of the display panel.

A material of the rigid substrate is not specifically limited herein. For example, the material of the rigid substrate may include glass.

Herein, thickness ranges of parts of the rigid substrate in the device setting region, the bending region and the binding region are not specifically limited. For example, thicknesses of the part of the rigid substrate in the device provision area and of the part of the rigid substrate in the binding area may be the same or different. For example, thicknesses of the part of the rigid substrate in the device provision area and of the part in the binding area in the direction perpendicular to the display baseplate may each range from 0.3 mm to 0.6 mm, and specifically, the thickness of the part of the rigid substrate in the device provision area in the direction perpendicular to the display baseplate may be 0.3 mm, 0.4 mm, 0.5 mm or 0.6 mm, etc.; and the thickness of the part of the rigid substrate in the binding area in the direction perpendicular to the display baseplate can be 0.3 mm, 0.4 mm, 0.5 mm or 0.6 mm, etc. For example, the thickness of the part of the rigid substrate in the bending area in the direction perpendicular to the display baseplate can range from 0.03 to 0.07 mm. Specifically, the thickness of the part of the rigid substrate in the bending area in the direction perpendicular to the display baseplate can be 0.03 mm, 0.04 mm, 0.05 mm, 0.06 mm or 0.03 mm, etc., so that this the ultra-thin rigid substrate can be bent.

A manufacturing process of the part of the rigid substrate located in the bending region is not specifically limited herein. For example, the part of the rigid substrate located in the bending area can be thinned by a half-etching process. Taking a glass substrate as the rigid substrate as an example, a specific etching thinning process flow can be as follows: 1. coating an acid-proof film on a glass substrate; 2. etching and thinning the bending area, for example, treating the bending area with a mixed acid solution, in which specifically chemical thinning can be performed with a mixed acid solution mainly containing hydrofluoric acid, with a reaction formula of HF+SiO₂→H₂SiF₆+H₂O; 3. stripping the film; and 4. polishing.

It should be noted that the display baseplate can be made directly on the rigid substrate, and this design requires no substrate stripping and treatment in the EAC section, which is simple and easy to implement.

Optionally, as shown in FIG. 13, the thickness of the part of the rigid substrate 11 located in the device provision area D1 in the direction perpendicular to the display baseplate 2 is equal to the thickness of the part of the rigid substrate 11 located in the binding area D3 in the direction perpendicular to the display baseplate 2. A side, away from the display baseplate 2, of the part of the rigid substrate 11 located in the bending region D2 is arranged in an arched shape. In this way, the rigid substrate is conveniently manufactured, and the method is simple and easy to implement.

Optionally, as shown in FIGS. 12 and 13, the display panel further includes a heat dissipation layer 5 and a spacer 6 stacked on a side of the rigid substrate 11 away from the display baseplate 2, and both the heat dissipation layer 5 and the spacer 6 are located in the device provision area D1. The part of the rigid substrate 11 located in the binding area D3 is configured to contact the spacer 6 after the part of the rigid substrate 11 located in the bending area D2 is bent along the bending axis. In this way, the display panel can be well heat dissipated by the heat dissipation layer, and the strength during bonding is ensured by the rigid substrate, thus ensuring the binding effect.

A material of the heat dissipation layer is not specifically limited herein. For example, the material of the heat dissipation layer can be copper foil, foam, etc.

A material of the spacer is not specifically limited herein. For example, a material of the spacer can be platinum (Pt).

It should be noted that, as shown in FIGS. 12 and 13, the driving unit 4 is arranged on a side of the rigid substrate 11 close to the display baseplate 2, and is located in the binding area D3.

An embodiment of the present disclosure further provides a display apparatus including the display panel described above.

The display apparatus may be a display apparatus with a touch function, or a display apparatus with a folding or curling function, or a display apparatus with both the touch function and the folding function, which is not limited herein. The display apparatus can be a flexible display apparatus (also known as a flexible screen) or a rigid display apparatus (i.e., a display panel that cannot be bent), which is not limited herein.

The display apparatus may be an OLED display apparatus, a Micro LED display apparatus or a Mini LED display apparatus, and may also be an LCD (Liquid Crystal Display) display apparatus.

The display apparatus can be any product or component with the display function such as a TV, a digital camera, a mobile phone, a tablet computer, etc. The display apparatus can also be applied to fields such as identity recognition, medical devices and the like, and products that have been popularized or have good popularization prospects involve security identity authentication, intelligent door locks, medical image acquisition and the like. The display apparatus has advantages of good supporting strength, a narrow border, low cost, good display effect, long service life, high stability, high contrast, good imaging quality and good product quality.

The term “embodiment” in this specification means that specific features, structures, or characteristics described in conjunction with the embodiment are included in at least one embodiment of the present disclosure.

In the specification provided here, a large number of specific details are explained. However, it can be understood that the embodiments of the present disclosure can be practiced without these specific details. In some examples, well-known methods, structures, and techniques are not shown in detail to avoid blurring the understanding of this specification.

Finally, it should be noted that the above embodiments are only used to illustrate the technical solution of the present disclosure, and not to limit it. Although the present disclosure has been described in detail with reference to the aforementioned embodiments, persons skilled in the art should understand that they can still modify the technical solutions recorded in the aforementioned embodiments, or equivalently replace some of the technical features therein. And these modifications or replacements do not make the essence of the corresponding technical solutions deviate from the spirit and scope of the technical solutions in the various embodiments of the present disclosure.

1. A display panel, comprising a device provision area, a bending area and a binding area, wherein the bending area is located between the device provision area and the binding area; and
the display panel further comprises a substrate and a display baseplate arranged on the substrate, the display baseplate is located in the device provision area; the substrate is located in the device provision area, the bending area and the binding area, the substrate at least comprises a rigid substrate, and a part of the substrate located in the bending area is configured to be bendable along a bending axis.

2. The display panel according to claim 1, wherein the substrate comprises the rigid substrate and a flexible substrate disposed between the rigid substrate and the display baseplate; wherein the rigid substrate is located in the device provision area; the flexible substrate is located in the device provision area, the bending area and the binding area, and a part of the flexible substrate located in the bending area is configured to be bendable along the bending axis; and
the display panel further comprises a plurality of driving units provided on a side of the flexible substrate close to the display baseplate, and the plurality of driving units are uniformly distributed in the binding area.

3. The display panel according to claim 2, wherein a length of the part of the flexible substrate located in the bending area in a direction parallel to the display baseplate is different from at least one of a length of a part of the flexible substrate located in the device provision area in the direction parallel to the display baseplate and a length of a part of the flexible substrate located in the binding area in the direction parallel to the display baseplate.

4. The display panel according to claim 3, wherein the length of the part of the flexible substrate located in the bending area in the direction parallel to the display baseplate is respectively less than the length of the part of the flexible substrate located in the device provision area in the direction parallel to the display baseplate and the length of the part of the flexible substrate located in the binding area in the direction parallel to the display baseplate.

5. The display panel according to claim 4, wherein at least one cut corner is respectively provided at a side, close to the bending area, of the part of the flexible substrate located in the device provision area and a side, close to the bending area, of the part of the flexible substrate located in the binding area.

6. The display panel according to claim 4, wherein the part of the flexible substrate located in the bending area and the part of the flexible substrate located in the binding area both comprise a plurality of flexible substrate sections that are disconnected, and a through groove is provided between adjacent flexible substrate sections; and
respective driving units are arranged on respective flexible substrate sections.

7. The display panel according to claim 6, wherein an orthographic projection of an outer contour of the through groove on the substrate comprises a first line segment, a second line segment and a third line segment, the first line segment is arranged close to the device provision area, and one end of the first line segment is connected to the second line segment and the other end of the first line segment is connected to the third line segment.

8. The display panel according to claim 7, wherein the orthographic projection of the outer contour of the through groove on the substrate further comprises a fourth line segment and a fifth line segment; and
one end of the first line segment is connected to the second line segment through the fourth line segment, and the other end of the first line segment is connected to the third line segment through the fifth line segment.

9. The display panel according to claim 2, wherein the display panel further comprises a heat dissipation layer and a spacer stacked on a side of the rigid substrate away from the display baseplate, and both the heat dissipation layer and the spacer are located in the device provision area; and
the display panel further comprises a support layer provided on a side of the flexible substrate away from the display baseplate, the support layer is located in the binding area, and orthographic projections of the driving units on the flexible substrate are located within an orthographic projection of the support layer on the flexible substrate; the support layer is configured to contact the spacer after the part of the flexible substrate located in the bending region is bent along the bending axis.

10. The display panel according to claim 1, wherein the substrate comprises the rigid substrate, the rigid substrate is located in the device provision area, the bending area and the binding area; and a part of the rigid substrate located in the bending region is configured to be bendable along the bending axis.

11. The display panel according to claim 10, wherein a thickness of the rigid substrate in the direction perpendicular to the display baseplate is uniform.

12. The display panel according to claim 11, wherein the thickness of the rigid substrate in the direction perpendicular to the display baseplate ranges from 0.03 mm to 0.07 mm.

13. The display panel according to claim 12, wherein a thickness of the part of the rigid substrate located in the bending area in the direction perpendicular to the display baseplate is respectively less than a thickness of a part of the rigid substrate located in the device provision area in the direction perpendicular to the display baseplate and a thickness of a part of the rigid substrate in the binding area in the direction perpendicular to the display baseplate.

14. The display panel according to claim 12, wherein the display panel further comprises a heat dissipation layer and a spacer stacked on a side of the rigid substrate away from the display baseplate, both the heat dissipation layer and the spacer are located in the device provision area; and the part of the rigid substrate located in the binding area is configured to contact the spacer after the part of the rigid substrate located in the bending area is bent along the bending axis.

15. A display apparatus, comprising the display panel according to claim 1.
